(19) United States
(12) Patent Application Publication
(10) Pub. No.: US 2025/0048620 A1
(43) Pub. Date: Feb. 6, 2025

(54) MEMORY DEVICE AND MANUFACTURING METHOD THEREOF

(71) Applicant: Winbond Electronics Corp., Taichung City (TW)

(72) Inventors: Ying-Hung Chen, Tainan (TW); Chun-Chieh Wang, Taichung City (TW); Tzu-Ming Ou Yang, Taichung City (TW)

(73) Assignee: Winbond Electronics Corp., Taichung City (TW)

(21) Appl. No.: 18/460,610

(22) Filed: Sep. 4, 2023

(30) Foreign Application Priority Data
Aug. 1, 2023 (TW) 112128764

(51) Int. Cl. H10B 12/00

(52) U.S. Cl. CPC H10B 12/488; H10B 12/053; H10B 12/34

(57) ABSTRACT

A memory device and a manufacturing method are provided. The memory device includes active regions defined in a semiconductor substrate by an isolation structure, wherein the active regions are arranged as an array along first and second directions, and extend along a third direction; and word lines, extending through the active regions along the second direction in the semiconductor substrate. The active regions are arranged in pairs along the second direction. The active regions in the same pair are closely adjacent to each other by a first spacing. Adjacent pairs of the active regions are separated by a greater second spacing. A featured portion of each active region below an intersecting word line has a first side closely adjacent to the other active region in the same pair by the first spacing and a second side separated from another pair of the active regions by the second spacing, and has an inclined top surface ascending from the second side to the first side.

### CROSS-REFERENCE TO RELATED APPLICATION

This application claims the priority benefit of Taiwan application serial no. 112128764, filed on Aug. 1, 2023. The entirety of the above-mentioned patent application is hereby incorporated by reference herein and made a part of this specification.

### BACKGROUND

### Technical Field

The present disclosure relates to a semiconductor device and a manufacturing method thereof, and particularly, to a memory device and a manufacturing method thereof.

### Description of Related Art

Dynamic random access memory (DRAM) is a comprehensively used volatile memory. Each DRAM cell includes an access transistor and a storage capacitor coupled to the access transistor. Along with development of DRAM manufacturing process, integration density of DRAM has been significantly improved. Such improvement in integration density involves reduction of spacing between active regions of the access transistors. By disposing DRAM cells with greater density, more DRAM cells can be included in a given area, thus storage density of DRAM can be increased. Moreover, while further raising integration density, performance of the access transistors is expected to be improved, so as to further enhance overall performance of DRAM.

### SUMMARY

In an aspect of the present disclosure, a memory device is provided. The memory device comprises: active regions, defined in a semiconductor substrate by an isolation structure, and are arranged as an array along a first direction and a second direction, wherein each of the active regions extends along a third direction intersected with the first direction and the second direction; and word lines, formed in the semiconductor substrate, and extending through the active regions along the second direction, wherein the active regions are arranged in pairs along the second direction, the active regions in the same pair are closely adjacent to each other by a first spacing, adjacent pairs of the active regions are separated from each other by a second spacing greater than the first spacing, a featured portion of each active region right below an intersecting one of the word lines has a first side closely adjacent to the other active region in the same pair by the first spacing as well as a second side separated from an adjacent pair of the active regions by the second spacing, and has a inclined top surface ascending from the second side to the first side.

In another aspect of the present disclosure, a method for manufacturing a memory device is provided. The method comprises: defining active regions in a semiconductor substrate by an isolation structure, wherein the active regions are arranged as an array along a first direction and a second direction, each of the active regions extends along a third direction intersected with the first direction and the second direction, the active regions are arranged in pairs along the second direction, the active regions in the same pair are closely adjacent to each other by a first spacing, and adjacent pairs of the active regions are separated from each other by a second spacing greater than the first spacing; forming a mask pattern on the semiconductor substrate, wherein the mask pattern has openings extending along the second direction; performing multiple etching processes by using the mask pattern as a shadow mask, to form trenches extending through the isolation structure and the active regions, wherein as a result of the etching processes, a feature portion of each active region right below an intersecting one of the trenches has a first side closely adjacent to the other active region in the same pair by the first spacing as well as a second side separated from an adjacent pair of the active regions by the second spacing, and has a inclined top surface ascending from the second side to the first side; and filling word lines into the trenches.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic plan view illustrating a memory device, according to some embodiments of the present disclosure.

FIG. 1B is a schematic cross-sectional view along A-A′ line shown in FIG. 1A.

FIG. 1C is a schematic cross-sectional view along B-B′ line shown in FIG. 1A.

FIG. 2 is a flow diagram illustrating a method for forming the active regions and the word lines in the memory device, according to some embodiments of the present disclosure.

FIG. 3A through FIG. 3J are schematic cross-sectional views illustrating intermediate structures at various stages during the manufacturing process shown in FIG. 2.

### DESCRIPTION OF THE EMBODIMENTS

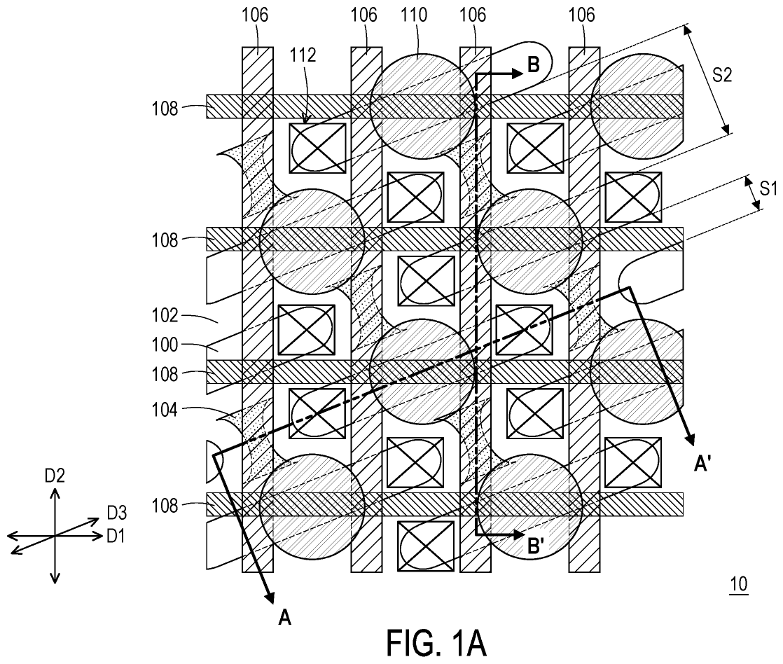

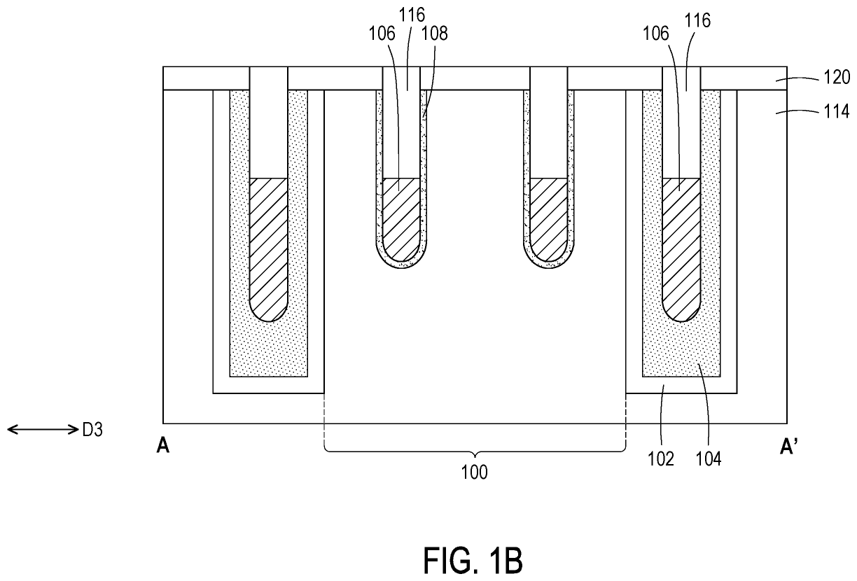

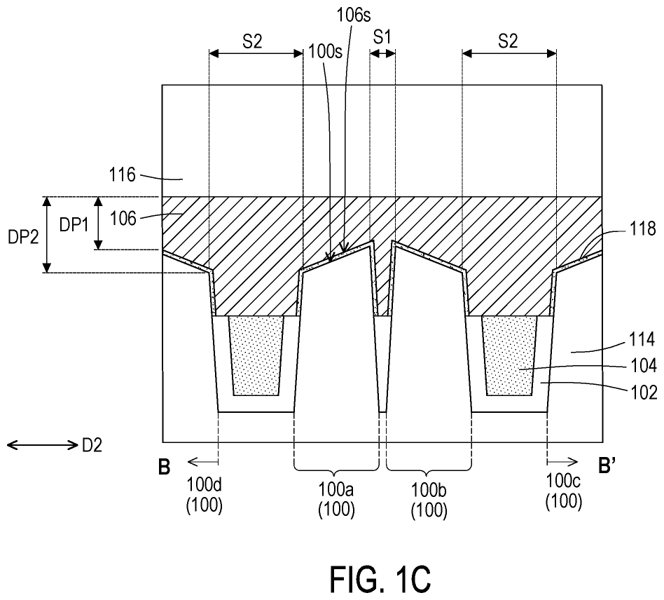

FIG. 1A is a schematic plan view illustrating a memory device 10, according to some embodiments of the present disclosure. The memory device 10 is such as a DRAM array including multiple DRAM cells. Each DRAM cell includes an access transistor and a storage capacitor coupled to the access transistor. For clarity, the storage capacitors disposed over the access transistors are not depicted in FIG. 1A. In addition, most insulating components are omitted in FIG. 1A. At least some insulating components will be described with reference to FIG. 1B and FIG. 1C.

Referring to FIG. 1A, the memory device 10 includes multiple active regions 100. Each active region 100 may be a portion of a semiconductor substrate (i.e., the semiconductor substrate 114 to be described with reference to FIG. 1B and FIG. 1C). An isolation structure 102 formed into the semiconductor substrate laterally surrounds each of the active regions 100, to as to electrically isolate the active regions 100 from one another.

The active regions 100 in each row are arranged along a direction D1, and the active regions 100 in each column are arranged along a direction D2 intersected with (e.g., perpendicular to) the direction D1. The active regions 100 in each row may be offset with respect to the active regions 100 in an adjacent row. Similarly, the active regions 100 in each column may be offset with respect to the active regions 100 in an adjacent column. In addition, each active region 100 may extend along a direction D3 intersected with the direction D1 and the direction D2. Separate insulating structures 104 are embedded in the isolation structure 102, and are each located between adjacent active regions 100 arranged along the direction D3. In some embodiments, each of the insulating structures 104 is laterally recessed in corresponding to the nearest active regions 100 by opposite sides, and in a double concave shape.

Word lines 106 extend along the direction D2 through an array of the active regions 100. Each DRAM cell is defined at an intersection of one of the word lines 106 and one of the active regions 100. For each access transistor, the word line 106 extending through is functioned as a gate terminal, whereas portions of the intersected active region 100 at opposite sides of this word line 106 are functioned as source and drain terminals. To allow each active region 100 to be shared by two access transistors, each active region 100 is intersected with two of the word lines 106. In this way, portions of each active region 100 located between the two intersected word lines 106 may be functioned as a common source/drain terminal of the sitting access transistors.

Bit lines 108 extend along the direction D1 over the semiconductor substrate, and respectively intersect with a row of the active regions 100. The portion of each active region 100 functioned as a common source/drain terminal may be connected to an overlying one of the bit lines 108 through a bit line contact structure 110. As described, each active region 100 may be intersected with two of the word lines 106, and such portion of each active region 100 as the common source/drain terminal may be located between the two intersecting word lines 106. Therefore, each active region 100 may be overlapped with the overlying bit line contact structure 110 and bit line 108 by the portion between the intersecting word lines 106.

On the other hand, portions of each active region 100 at opposite sides of the intersecting word lines 106 may be respectively connected to an overlying storage capacitor (not shown) via a capacitor contact structure 112. That is, each active region 100 is overlapped with two of the capacitor contact structures 112 by opposite ends. Although not shown, the storage capacitors respectively connected to one of the capacitor contact structures 112 may be disposed over the bit line contact structures 110, the capacitor contact structures 112 and the bit lines 108. These storage capacitors may include multiple bottom electrodes separated from one another and each connected to one of the capacitor contact structures 112, and may share a common dielectric layer and a common top electrode.

Owing to the staggered configuration (i.e., row-to-row offset and column-to-column offset), each word line 106 intersects with some of the active regions 100, and overlaps the isolation structure 102 and the insulating structures 104 in between these active regions 100. The active regions 100 intersected with each word line 106 are arranged by pairs. The active regions 100 in each pair are closely adjacent to each other, while adjacent pairs of the active regions 100 are widely separated from each other. Along each word line 106, the active regions 100 in each pair are arranged between two of the insulating structures 104, and are widely separated from adjacent pairs of the active regions 100 via these two insulating structures 104. To be more specific, right below each word line 106, the active regions 100 in the same pair are closely adjacent to each other by a spacing S1, and adjacent pairs of the active regions 100 are separated by a spacing S2 greater than the spacing S1. That is, in the direction D2, each active region 100 is spaced apart from two nearest active regions 100 by different spacings (i.e., the spacing S1 and the spacing S2). As will be described in further details, during formation of the word lines 106, such unequal spacing may result that portions of each active region 100 extending along bottom surfaces of the intersecting word lines 106 respectively have an inclined top surface ascending from its long spacing side to its short spacing side. Correspondingly, sections of each word line 106 extending through the active regions 100 have inclined bottom surfaces.

FIG. 1B is a schematic cross-sectional view along A-A′ line shown in FIG. 1A, and FIG. 1C is a schematic cross-sectional view along B-B′ line shown in FIG. 1A. It should be appreciated that, some of the components above the semiconductor substrate (e.g., the bit line contact structures 110, the capacitor contact structures 112 and the bit lines 108) are not shown in FIG. 1B and FIG. 1C.

Referring to FIG. 1B that schematically illustrates a cross-sectional view along an extending direction of the active regions 100 (i.e., the direction D3), the isolation structure 102 extends into a semiconductor substrate 114 from a top surface of the semiconductor substrate 114, and surrounds each of the active regions 100. In addition, the insulating structures 104 at opposite sides of each active region 100 extend into the isolation structure 102 from a top surface of the isolation structure 102, so as to be wrapped by the isolation structure 102. According to some embodiments, the isolation structure 102 and the insulating structures 104 embedded in the isolation structure 102 are formed by different insulating materials. As an example, the isolation structure 102 may be formed by silicon oxide, while the insulating structure 104 may be formed by silicon nitride.

As shown in FIG. 1B, the word lines 106 are embedded in the semiconductor substrate 114, and may extend through the active regions 100, the isolation structure 102 and the insulating structures 104 embedded in the isolation structure 102. In addition, the word lines 106 may be each formed in a bottom portion of a trench extending into the semiconductor substrate 114, and an upper portion of each of these trenches is filled by an insulating plug 116. Further, sections of each trench that extend through the active regions 100 may be respectively lined with a gate dielectric layer 118, such that the word lines 106 and the insulating plugs 116 in the trenches are separated from the active regions 100 via the gate dielectric layers 118. On the other hand, sections of each trench that extend through the isolation structure 102 and the insulating structures 104 are deeper than the sections of each trench that extend through the active regions 100, and are not covered by the gate dielectric layers 118. In this way, portions of the word lines 106 in the sections of the trenches that extend through the isolation structure 102 and the insulating structures 104 may have a greater depth, as compared to portions of the word lines 106 in the sections of the trenches that extend through the active regions 100. Further, the portions of the word lines 106 and the insulating plugs 116 in the sections of the trenches that extend through the isolation structure 102 and the insulating structures 104 are not covered by the gate dielectric layers 118. According to some embodiments, an insulating liner layer 120 extends along the top surfaces of the semiconductor substrate 114, the isolation structure 102 and the insulating structures 104. In these embodiments, the trenches accommodating the word lines 106 and the insulating plugs 116 penetrate through the insulating liner layer 120, and extend into the active regions 100, the isolation structure 102 and the insulating structures 104. Moreover, although not shown, each word line 106 may have a conductive material as a body portion and a conductive barrier layer covering the conductive material.

FIG. 1C schematically illustrates a cross-sectional view of one of the word lines 106. As indicated by FIG. 1C, the sections of the word lines 106 that extend through the isolation structure 102 and the insulating structures 104 have a greater depth, as compared to the sections of the word lines 106 that extend through the active regions 100. Accordingly, portions of the active regions 100 that lie below the word lines 106 protrude with respect to portions of the isolation structure 102 and the insulating structures 104 that lie below the word lines 106. In addition, the active regions 100 intersected with each word line 106 are arranged by pairs along an extending direction of the word lines 106 (i.e., the direction D2). The active regions 100 in each pair (e.g., active regions 100a, 100b) are closely adjacent to each other by a spacing S1, and is separated by the isolation structure 102. Further, each pair of the active regions 100 (e.g., the active regions 100a, 100b) are spaced apart from an adjacent pair of the active regions 100 (e.g., one including an active region 100c or another one including an active region 100d) by a spacing S2 greater than the spacing S1, and the isolation structure 102 as well as one of the insulating structures 104 are filled in between adjacent pairs of the active regions 100.

As a result, portions of each active region 100 right below the intersected word lines 106 respectively have a first side spaced apart from an adjacent active region 100 by the short spacing S1, and have a second side spaced apart from another adjacent active region 100 by the large spacing S2. Owing to difference in etching, the portions of each active region 100 right lie below the intersected word lines 106 respectively have an inclined top surface 100s ascending from the second side to the first side along the direction D2. As a consequence, the cross-sectional view cut along the direction D2 shows that the portions of each active region 100 right below the intersected word lines 106 are respectively in a shape of a tip portion of a utility knife. Correspondingly, each word line 106 has inclined bottom surfaces 106s extending along the inclined top surfaces 100s of the underlying active regions 100. In addition, each word line 106 extends to the first sides of the underlying active regions 100 by a first depth DP1, while extending to the second sides of the underlying active regions 100 by a second depth DP2 greater than the first depth DPL. Moreover, the gate dielectric layers 118 lining between the word lines 106 and the active regions 100 also extend along the inclined top surfaces 100s of the active regions 100.

As the active regions 100 intersected with each word line 106 are periodically arranged by pairs along the direction D2, the active regions 100 in the same pair (e.g., the active regions 100a, 100b) are symmetric with respect to a central axis in between. In this way, the inclined top surfaces 100s of the active regions 100 in the same pair (e.g., the active regions 100a, 100b) ascend toward the central axis in between. In addition, each active region 100 may be symmetric with an adjacent active region 100 spaced apart by the spacing S2 (e.g., the active regions 100b, 100c or the active regions 100a, 100d), such that the inclined top surfaces 100s of the active regions 100 spaced apart by the spacing S2 may descend toward a central axis in between.

On the other hand, portions of the isolation structure 102 and the insulating structures 104 right below the word lines 106 are not limited to having top surfaces ascending/descending along the direction D2, and portions of each word line 106 that cover the isolation structure 102 and the intersected insulating structures 104 may have corresponding bottom surfaces. For instance, the portions of the isolation structure 102 and the insulating structures 104 may have top surfaces substantially flat or concave (observed from the cut along the direction D2). Correspondingly, the portions of each word line 106 that cover the isolation structure 102 and the intersected insulating structures 104 may have bottom surfaces substantially flat or convex (in the direction D2).

Moreover, portions of each active region 100 that are not intersected with any of the word lines 106 are not limited to having top surfaces ascending/descending along the direction D2. For instance, these portions of each active region 100 may have substantially flat, convex or concave (observed from the cut along the direction D2) top surfaces.

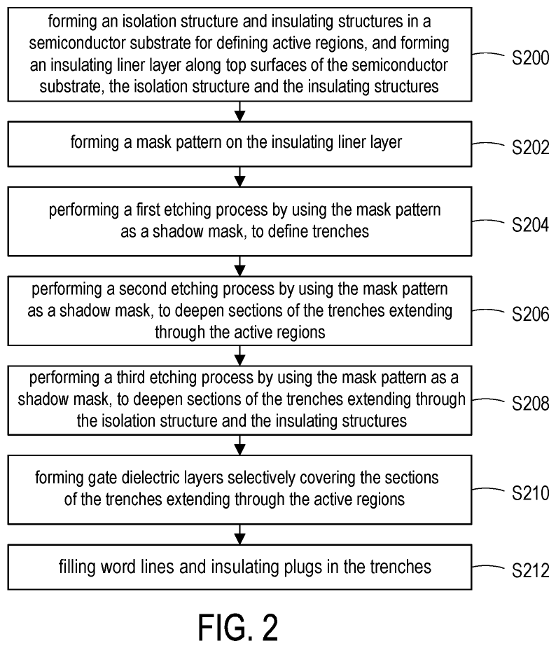

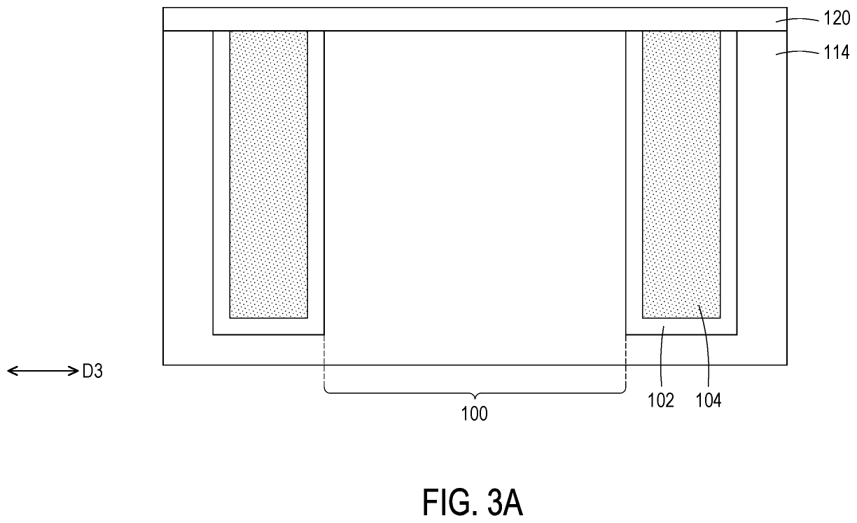

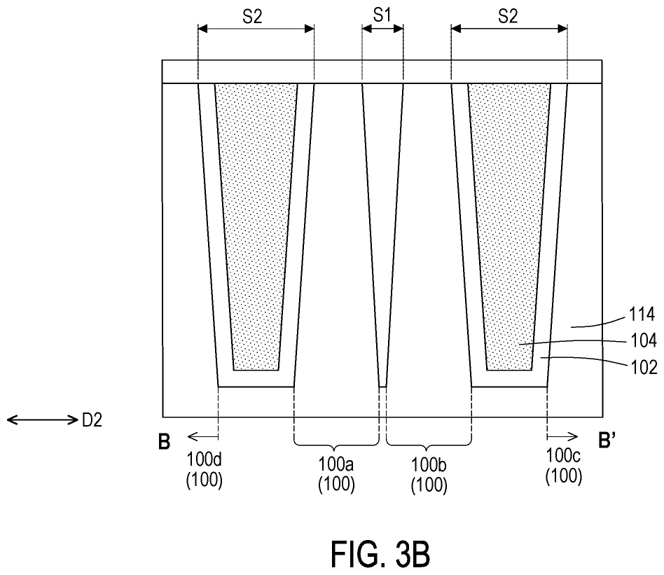

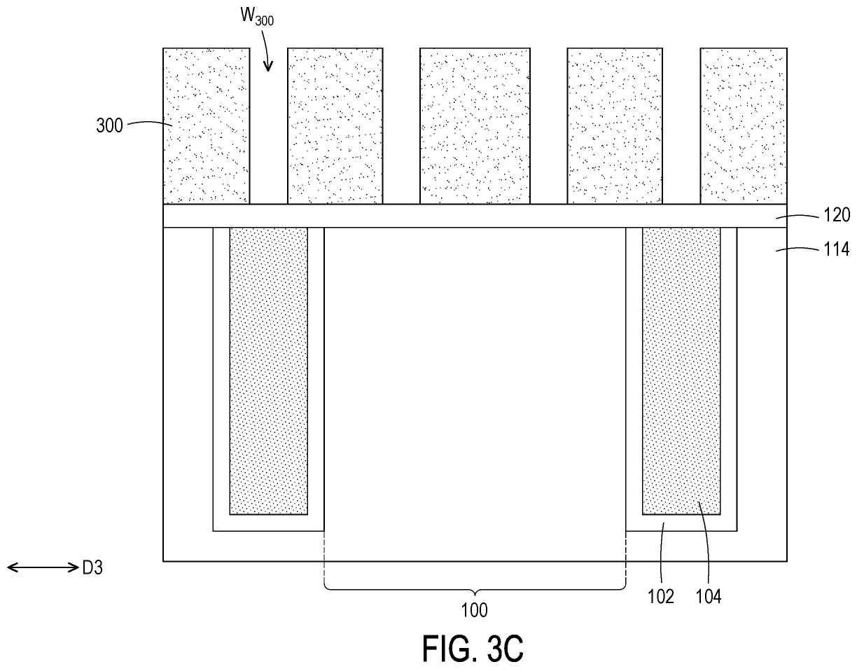

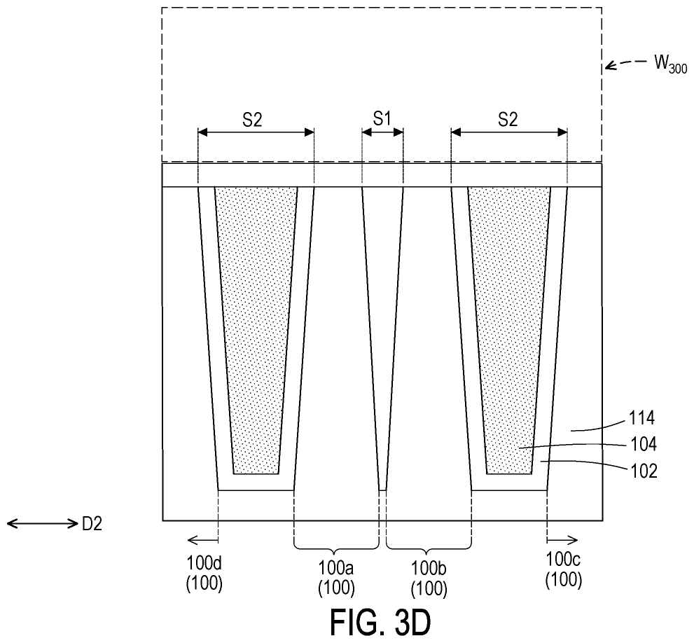

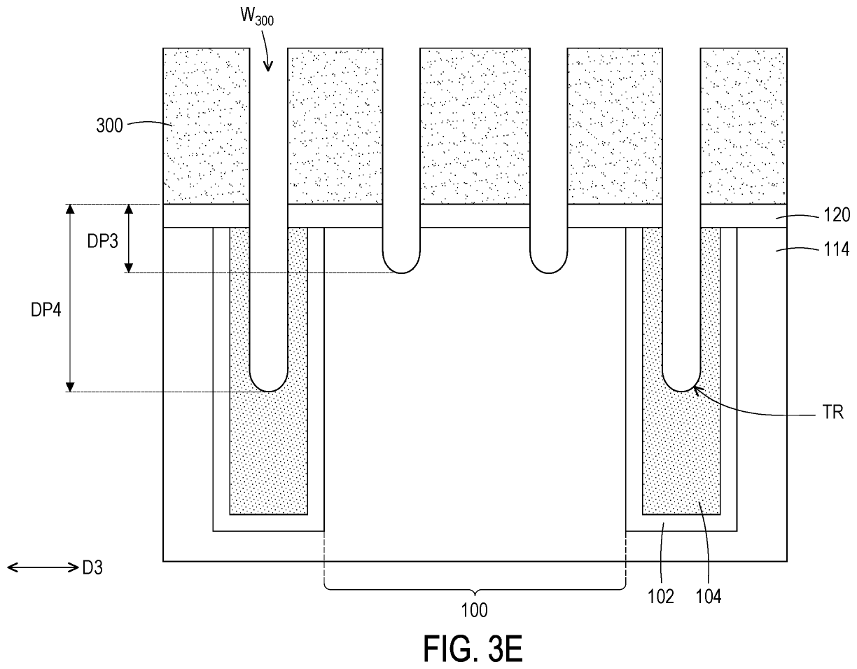

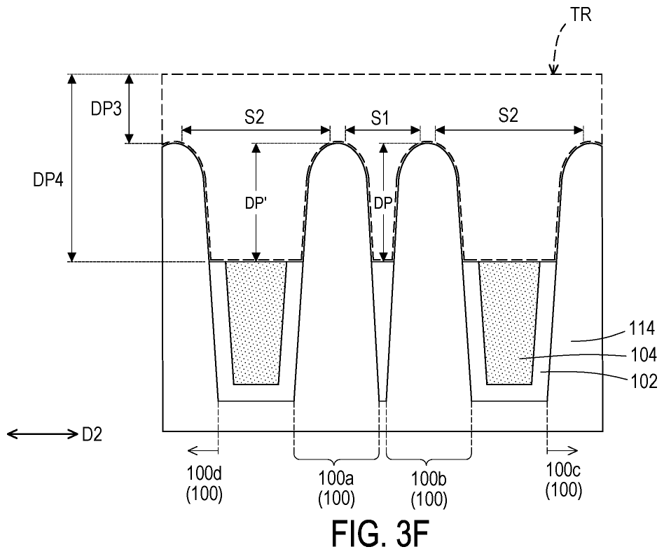

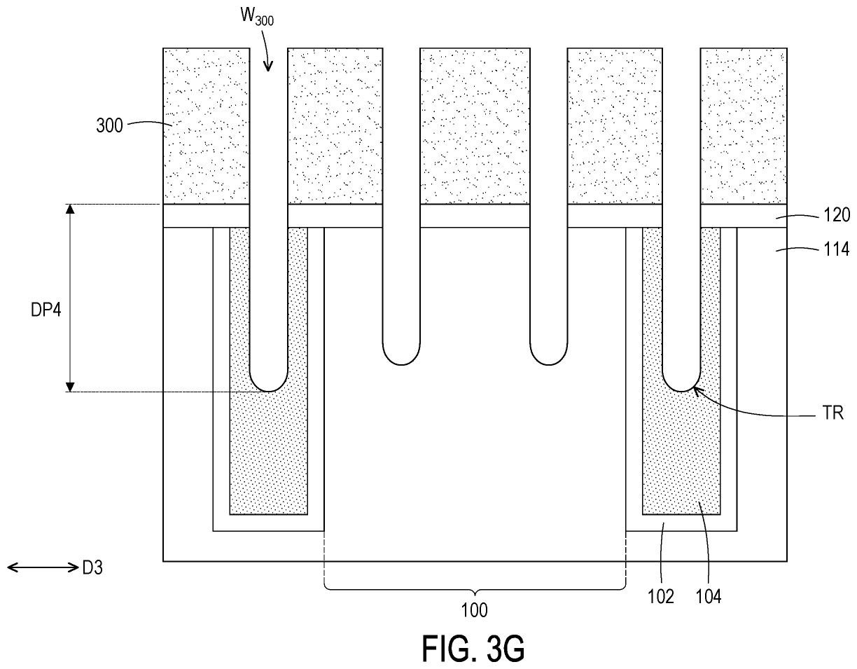

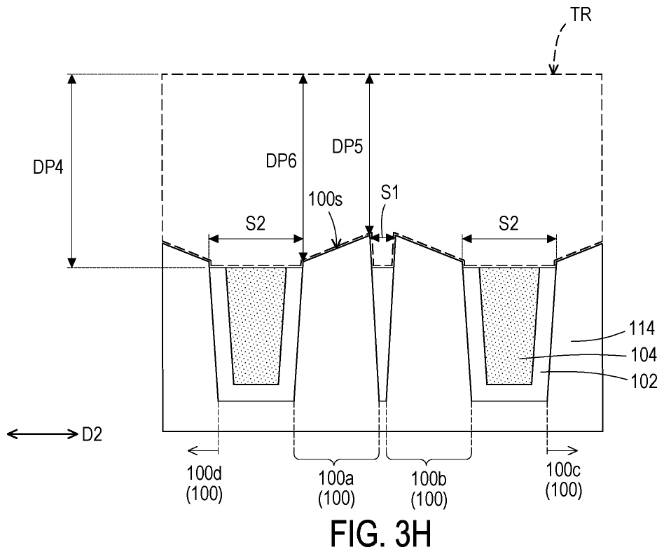

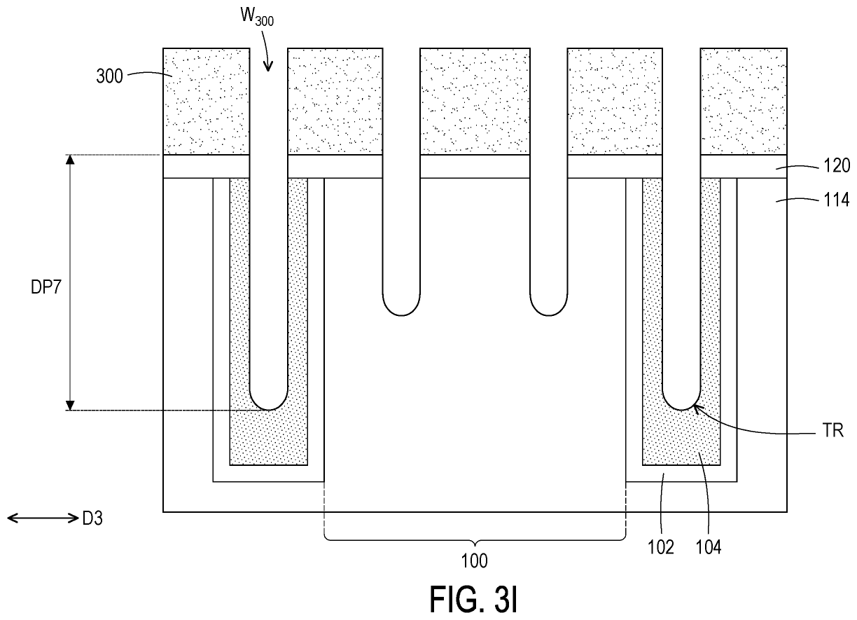

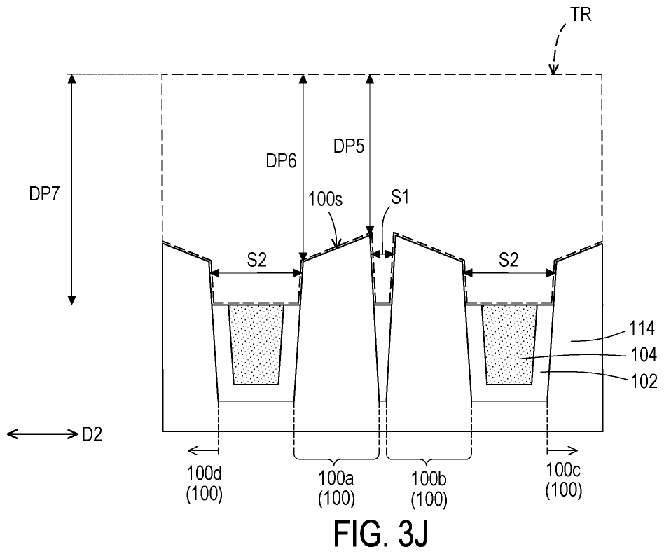

The active regions 100 and the word lines 106 have these featured structures because of the arrangement of the active regions 100 and how the active regions 100 are shaped during manufacturing. Formation of the active regions 100 and the word lines 106 will be described with reference to FIG. 2 and FIG. 3A through FIG. 3J.

FIG. 2 is a flow diagram illustrating a method for forming the active regions 100 and the word lines 106, according to some embodiments of the present disclosure. FIG. 3A through FIG. 3J are schematic cross-sectional views illustrating intermediate structures at various stages during the manufacturing process shown in FIG. 2. Particularly, FIG. 3A, FIG. 3C, FIG. 3E, FIG. 3G and FIG. 3I are cross-sectional views cutting one of the active regions 100 along an extending direction of this active region 100 (i.e., the direction D3). On the other hand, FIG. 3B, FIG. 3D, FIG. 3F, FIG. 3H and FIG. 3J are cross-sectional views cutting one of the word lines 106 along an extending direction of this word line 106 (i.e., direction D2).

Referring to FIG. 2, FIG. 3A and FIG. 3B, at a step S200, the isolation structure 102 and the insulating structures 104 are formed in the semiconductor substrate 114, and the insulating liner layer 120 is formed along the top surfaces of the semiconductor substrate 114, the isolation structure 102 and the insulating structures 104. Specifically, the isolation structure 102 may be formed into the semiconductor substrate 114 at first, and the insulating structures 104 may be subsequently formed in the isolation structure 102. After performing a possible planarization process, the liner layer 120 is formed on the semiconductor substrate 114, the isolation structure 102 and the insulating structures 104. The active regions 100 are defined in the semiconductor substrate 114 by the isolation structure 102. As shown in FIG. 3B, the active regions 100 are arranged in pairs along the direction D2. The active regions 100 in the same pair (e.g., the active regions 100a, 100b) are closely adjacent to each other by the spacing S1, and adjacent pairs of the active regions 100 (e.g., one including the active region 100c and another one including the active region 100d) are spaced apart by the spacing S2 larger than the spacing S1.

Referring to FIG. 2, FIG. 3C and FIG. 3D, at a step S202, a mask pattern 300 is formed on the insulating liner layer 120. The mask pattern 300 has multiple openings W₃₀₀. The opening W₃₀₀ will be used in a following step for defining locations of the trenches accommodating the word lines 106. That is, locations and width of the openings W₃₀₀ will define locations and width of the word lines 106. As FIG. 3D is a cross-sectional view along one of the subsequently formed word lines 106, what lies above the insulating liner 120 in FIG. 3D is one of the continuously extending openings W₃₀₀ (depicted in ghost lines). According to some embodiments, the mask pattern 300 is a hard mask pattern, such as a hard mask pattern formed of diamond-like carbon (DLC).

Referring to FIG. 2, FIG. 3E and FIG. 3F, at a step S204, the current structure is subjected to a first etching process by using the mask pattern 300 as a shadow mask. In this way, trenches TR penetrating through the insulating liner layer 120 and extending into the active regions 100, the isolation structure 102 and the insulating structures 104 are formed. Cross-sectional views of some of the trenches TR are shown in FIG. 3E, and one of the trenches TR is depicted in ghost lines in FIG. 3F. By properly selecting etchants for the first etching process, the first etching process can mainly target the isolation structure 102 and the insulating structures 104. As a result, sections of the trenches TR that extend through the isolation structure 102 and the insulating structures 104 are deeper than sections of the trenches TR that extent through the active regions 100. By adjusting etching time, the sections of the trenches TR extending through the active regions 100 may have a depth DP3, while the sections of the trenches TR extending through the isolation structure 102 and the insulating structures 104 may have a depth DP4 much greater than the depth DP3.

In addition, as shown in FIG. 3F (showing a cross-section view cut along the direction D2), a narrow cut with a depth DP greater than the spacing S1 is formed between the closely adjacent active regions 100 in each pair (e.g., the active regions 100a, 100b). On the other hand, a wide cut with a depth DP′ greater than the spacing S1 and a width larger than a width of the narrow cut is formed between adjacent pairs of the active regions 100 separated from each other in the direction D2 by the spacing S2 (e.g., one including the active regions 100a, 100b and another one including the active region 100c/100d). As such, in the direction D2, each active region 100 is separated from adjacent active regions 100 at opposite sides by the narrow cut and the wide cut, respectively. As a consequence, portions of each active region 100 right below the intersecting trenches TR will be etched to have the inclined top surfaces. As an example, such etching result may be observed when an aspect ratio of the narrow cut (i.e., a ratio of the depth DP with respect to the spacing S1) ranges from 1.5 to 2.5 and an aspect ratio of the wide cut (i.e., a ratio of the depth DP′ with respect to the spacing S2) ranges from 0.6 to 1.2. As another example, such etching result may be obtained when the aspect ratio of the narrow cut is greater than 1.5 and the aspect ratio of the wide cut is less than 1.2. According to certain embodiments, a ratio of the depth DP of the narrow cut with respect to the depth DP′ of the wide cut is controlled to be ranging from 0.9 to 1, for obtaining the expected etching result.

Moreover, as indicated by FIG. 3F, the active regions 100 currently protrude with respect to the isolation structure 102 and the insulating structures 104 right below the trenches TR. Further, the portions of the active regions 100 right below the trenches TR are currently shaped to have rounded convex top surfaces (observed from the cut along the direction D2). In other embodiments, the portions of the active regions 100 right below the trenches TR are shaped to have other symmetric convex top surfaces (observed from the cut along the direction D2).

Referring to FIG. 2, FIG. 3G and FIG. 3H, at a step S206, the current structure is subjected to a second etching process by using the mask pattern 300 as a shadow mask. By properly selecting etchants for the second etching process, the second etching process can mainly target the active regions 100. As a result, the sections of the trenches TR that extend through the active regions 100 become greater in depth. In some embodiments, a depth of the sections of the trenches TR that extend through the active regions 100 is currently close to a depth of the sections of the trenches TR that extend through the isolation structure 102 and the insulating structures 104, which is substantially equal to or slightly greater than the depth DP4 shown in FIG. 3E and FIG. 3F.

As described with reference to FIG. 3F, the portions of the active regions 100 right below the trenches TR are respectively separated from adjacent active regions 100 at opposite sides by the narrow cut and the wide cut, respectively. This may result that the portions of the active regions 100 right below the trenches TR are respectively etched by different amount at the side close to the wide cut and the side close to the narrow cut, and therefore be shaped into an asymmetric structure. As shown in FIG. 3H, right below each trench TR, an etching depth at a side of each active region 100 close to a wide cut is greater than an etching depth at a side of each active region 100 close to a narrow cut. As a consequence, the rounded convex top surfaces of the portions of the active regions 100 right below the trenches TR are respectively shaped into an inclined top surface 100s. The inclined top surface 100s of an active region 100 ascends from the wide cut to the narrow cut at opposite sides of the active region 100. In this way, the trenches TR have a depth DP5 at an edge of each underlying active region 100 that is shared with a narrow cut, and have a depth DP6 at an edge of each underlying active region 100 that is shared with a wide cut. The depth DP6 is greater than the depth DP5. In addition, adjacent ones of the active regions 100 arranged along the direction D2 have the inclined top surfaces 100s tilting oppositely and symmetric with respect to a central axis in between.

Referring to FIG. 2, FIG. 3I and FIG. 3J, at a step S208, the current structure is subjected to a third etching process by using the mask pattern 300 as a shadow mask. By properly selecting etchants for the third etching process, the third etching process can mainly target the isolation structure 102 and the insulating structures 104. As a result, the sections of the trenches TR extending through the isolation structure 102 and the insulating structures 104 become greater in depth, and currently have a depth DP7 greater than the depth DP4 described with reference to FIG. 3E and FIG. 3G. On the other hand, the depth of the sections of the trenches TR extending through the active regions 100 may be substantially maintained or slightly increased. That is, the depth of the sections of the trenches TR extending through the active regions 100 may range from the depth DP5 to the depth DP6, or may be in a slightly greater range. Based on the selective etching, a depth difference between the sections of the trenches TR extending through the isolation structure 102 and the insulating structures 104 and the sections of the trenches TR extending through the active regions 100 is enlarged.

As shown in FIG. 3J, portions of the active regions 100 right below the trenches TR protrude more from the portions of the isolation structure 102 and the insulating structures 104 right below the trenches TR, and are resulted in the shape similar to a tip portion of a utility knife. Currently, the portions of the active regions 100 right below the trenches TR are protruded with respect to the portions of the isolation structure 102 right below the trenches TR by a greater height at the edges shared with the wide cuts, and are protruded with respect to the portions of the isolation structure 102 right below the trenches TR by a lower height at the edges shared with the narrow cuts. In addition, the inclined top surfaces 100s each extend from one of the wide cuts to one of the narrow cuts.

After performing the third etching process, the mask pattern 300 may be removed before a next step.

Referring to FIG. 2, FIG. 1B and FIG. 1C, at a subsequent step S210, the gate dielectric layers 118 are formed to selectively cover the sections of the trenches TR extending through the active regions 100. According to some embodiments, a thermal oxidation process is used for selectively forming the gate dielectric layers 118 on inner surfaces of the sections of the trenches TR extending through the active regions 100. Thereafter, at a step S212, the word lines 106 and the insulating plugs 117 are filled in the trenches TR.

Up to here, formation of the active regions 100 and the word lines 106 has been completed. Although not shown, further process steps are required to form components above the semiconductor substrate 114 (e.g., the bit line contact structures 110, the capacitor contact structures 112, the bit lines 108, the storage capacitors).

As above, a memory device and a manufacturing method thereof are provided. The memory device is a DRAM device, and includes access transistors defined at intersections of active regions and word lines as well as storage capacitors respectively connected to one of the access transistors. Alon an extending direction of the word lines, the active regions are arranged by pairs. The active regions in each pair are closely adjacent to each other by a first spacing, and adjacent pairs of the active regions are separated from each other by a second spacing greater than the first spacing. In this way, portions of each active region right below the intersected word lines respectively have a first side closely adjacent to another active region by the first spacing, and has a second side separated from another adjacent active region by the second spacing. Owing to such arrangement and proper control of etching processes, the portions of the active regions right below the word lines are respectively formed in an asymmetric structure similar to a tip portion of a utility knife, and respectively have an inclined top surface ascending from the second side to the first side. In addition, right below each word line, adjacent active regions closely adjacent to each other by the first spacing are symmetric with respect to a central axis, such that the inclined top surfaces of these adjacent active regions ascend toward the central axis in between. On the other hand, right below each word line, adjacent active regions separated from each other by the second spacing are symmetric with respect to a central axis as well, such that the inclined top surfaces of these adjacent active regions descend toward the central axis in between.

Owing to such featured structure, the access transistor can be operated with lower channel resistance (i.e., greater conducting current) and less sub-threshold swing. Accordingly, the access transistors are formed with greater driving ability and improved switching characteristics. Therefore, during operation of the memory device, the storage capacitors can be more effectively accessed.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
active regions, defined in a semiconductor substrate by an isolation structure, and are arranged as an array along a first direction and a second direction, wherein each of the active regions extends along a third direction intersected with the first direction and the second direction; and
word lines, formed in the semiconductor substrate, and extending through the active regions along the second direction,
wherein the active regions are arranged in pairs along the second direction, the active regions in the same pair are closely adjacent to each other by a first spacing, adjacent pairs of the active regions are separated from each other by a second spacing greater than the first spacing, a featured portion of each active region right below an intersecting one of the word lines has a first side closely adjacent to the other active region in the same pair by the first spacing as well as a second side separated from an adjacent pair of the active regions by the second spacing, and has a inclined top surface ascending from the second side to the first side.

2. The memory device according to claim 1, wherein the featured portion of each active region protrudes with respect to portions of the isolation structure lying right below the word lines.

3. The memory device according to claim 1, wherein first sections of the word lines extending through the active regions are formed to a depth less than a depth to which second sections of the word lines extending through the isolation structure are formed.

4. The memory device according to claim 3, wherein the first sections of the word lines respectively have an inclined bottom surface tilting along the second direction.

5. The memory device according to claim 1, wherein the word lines extend to the first side of the featured portion of each active region by a first depth, and extend to the second side of the featured portion of each active region by a second depth greater than the first depth.

6. The memory device according to claim 1, wherein the featured portion of each active region is an asymmetric structure.

7. The memory device according to claim 1, wherein the featured portions of the active region in the same pair are symmetric with respect to a central axis in between.

8. The memory device according to claim 1, wherein the featured portions of adjacent ones of the active regions separated from each other by the second spacing are symmetric with respect to a central axis in between.

9. The memory device according to claim 1, further comprising:
insulating structures, disposed in the isolation structure and separated from one another, wherein each active region extends between two of the insulating structures along the third direction, and the word lines extend through the insulating structures.

10. The memory device according to claim 9, wherein each insulating structure is placed in between two of the active regions separated from each other by the second spacing.

11. The memory device according to claim 1, further comprising:
bit lines, extending along the first direction over the semiconductor substrate, and overlapping the active regions.

12. The memory device according to claim 1, wherein each active region is separated from an intersecting one of the word lines by a gate dielectric layer.

13. The memory device according to claim 1, further comprising:
insulating plugs, disposed on the word lines, and respectively extending along one of the word lines.

14. A method for manufacturing a memory device, comprising:
defining active regions in a semiconductor substrate by an isolation structure, wherein the active regions are arranged as an array along a first direction and a second direction, each of the active regions extends along a third direction intersected with the first direction and the second direction, the active regions are arranged in pairs along the second direction, the active regions in the same pair are closely adjacent to each other by a first spacing, and adjacent pairs of the active regions are separated from each other by a second spacing greater than the first spacing;
forming a mask pattern on the semiconductor substrate, wherein the mask pattern has openings extending along the second direction;
performing multiple etching processes by using the mask pattern as a shadow mask, to form trenches extending through the isolation structure and the active regions, wherein as a result of the etching processes, a feature portion of each active region right below an intersecting one of the trenches has a first side closely adjacent to the other active region in the same pair by the first spacing as well as a second side separated from an adjacent pair of the active regions by the second spacing, and has a inclined top surface ascending from the second side to the first side; and
filling word lines into the trenches.

15. The method for manufacturing the memory device according to claim 14, wherein the etching processes comprise a first etching process, a second etching process and a third etching process performed in order.

16. The method for manufacturing the memory device according to claim 15, wherein the isolation structure is selectively targeted by the first etching process and the third etching process, and the active regions are selectively targeted by the second etching process.

17. The method for manufacturing the memory device according to claim 16, wherein as a result of the first etching process, a narrow cut with a depth-to-width ratio ranging from 1.5 to 2.5 is defined between the active regions in the same pair, and a wide cut with a depth-to-width ratio ranging from 0.6 to 1.2 is defined between adjacent pairs of the active regions.

18. The method for manufacturing the memory device according to claim 16, wherein different etching amounts are resulted from the second etching process for the first side and the second side of the featured portion of each active region, so as to result the inclined top surface of the featured portion of each active region.

19. The method for manufacturing the memory device according to claim 14, further comprising:
forming gate dielectric layers before formation of the word lines, wherein the gate dielectric layers cover sections of the trenches extending through the active regions.

20. The method for manufacturing the memory device according to claim 14, further comprising:
forming insulating plugs on the word lines after formation of the word lines, wherein each insulating plug extends along one of the word lines.
